(19) United States
(12) Patent Application Publication
(10) Pub. No.: US 2025/0306467 A1
(43) Pub. Date: Oct. 2, 2025

(54) LITHOGRAPHIC APPARATUS, INSPECTION METHOD, AND METHOD FOR PERFORMING LITHOGRAPHY PROCESS

(71) Applicant: TAIWAN SEMICONDUCTOR MANUFACTURING COMPANY, LTD., Hsinchu (TW)

(72) Inventors: Wei-Huai CHIU, Miaoli County (TW); Kueilin HO, Hsinchu County (TW); Chueh-Chi KUO, Kaohsiung City (TW); Cheng-Ying LIANG, Nantou County (TW); Han-Lung CHANG, Kaohsiung City (TW); Yu-Chi TSAI, Hsinchu County (TW)

(73) Assignee: TAIWAN SEMICONDUCTOR MANUFACTURING COMPANY, LTD., Hsinchu (TW)

(21) Appl. No.: 18/624,645

(22) Filed: Apr. 2, 2024

(51) Int. Cl. G03F 7/20; G03F 7/00

(52) U.S. Cl. CPC G03F 7/2004; G03F 7/70716; G03F 7/7085

(57) ABSTRACT

A lithography apparatus includes an exposure tool, a measurement tool, and a substrate table. The exposure tool is configured to provide a light pattern to a first position. The measurement tool includes a light source, a light receiver, and a fiber structure. The fiber structure has a first fiber, at least one second fiber, and a wall surrounding the first fiber and the second fiber. A first end of the first fiber is optically coupled with the light source, a first end of the second fiber is optically coupled with the light receiver, and a second end of the first fiber and a second end of the second fiber face a second position. The substrate table is configured to support a substrate. The substrate table is movable between the first position and the second position.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a lithography apparatus in accordance with some embodiments.

FIG. 2A is a schematic view of a fiber structure in accordance with some embodiments.

FIG. 2B is a schematic view of a fiber structure in accordance with some embodiments.

FIG. 3 is a flow chart of a method for operating a lithography apparatus in accordance with some embodiments.

FIGS. 4A-4F are respectively cross-sectional views of fiber structures in accordance with various embodiments.

FIGS. 5A and 5B illustrate inspecting a substrate in accordance with various embodiments.

FIG. 6A is a schematic side view illustrating a method of inspecting a substrate in accordance with various embodiments.

FIG. 6B is a schematic side view illustrating a method of inspecting a substrate in accordance with various embodiments.

FIG. 7 is a schematic side view illustrating a method of inspecting a substrate in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

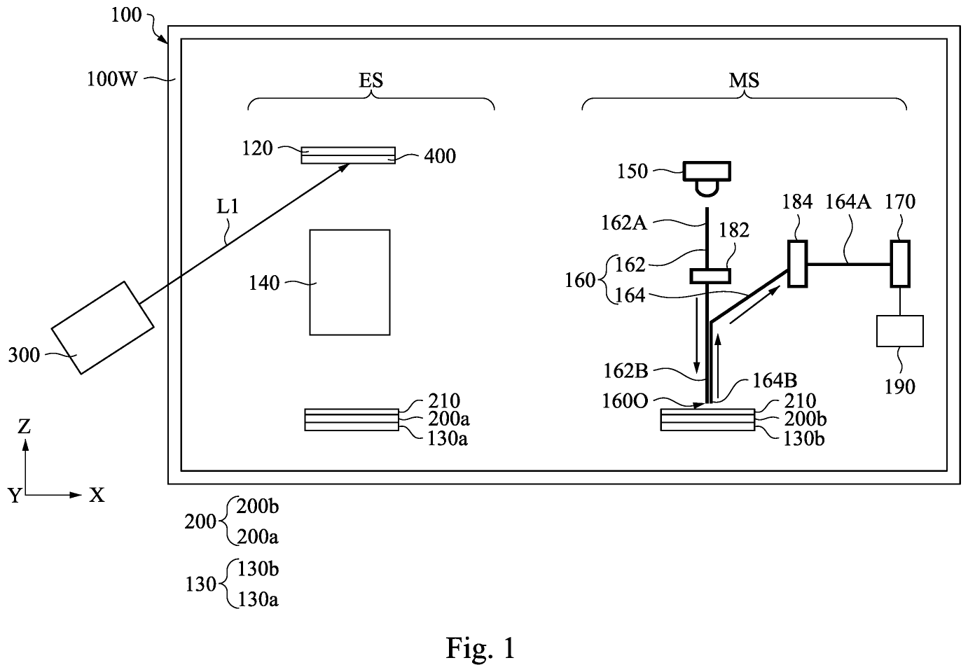

FIG. 1 is a schematic view of a lithography apparatus 100 in accordance with some embodiments. The lithographic apparatus 100 has two stations (e.g., an exposure station ES and a measurement station MS). In the context, the exposure station ES may also be referred to as an exposure tool, and the measurement station MS may also be referred to as a measurement tool. The lithographic apparatus 100 may has a wall 100W surrounding a chamber 100C, and the exposure tool and the measurement tool are disposed in the chamber 100C surrounded by the wall 100W. Substrate tables 130 in the exposure station ES and the measurement station MS are respectively labelled as substrate tables 130a and 130b. Substrates 200 in the exposure station ES and the measurement station MS are respectively labelled as substrates 200a and 200b. In some embodiments, two substrate tables 130a and 130b can be exchanged between the exposure station ES and the measurement station MS. While one substrate (e.g., one of the substrates 200a and 200b) on one substrate table (one of the substrate tables 130a and 130b) is being exposed at the exposure station ES, another substrate (e.g., the other one of the substrates 200a and 200b) can be loaded onto the other substrate table (the other one of the substrate tables 130a and 130b) at the measurement station MS.

Over the exposure station ES, the lithography apparatus 100 may perform lithography exposing processes with the respective radiation source 300 to expose a resist layer 210 over a semiconductor substrate 200 (e.g., one of the substrates 200a and 200b). In the present embodiments, the semiconductor substrate 200 is a semiconductor wafer, such as a silicon wafer or other type of wafer to be patterned. The semiconductor substrate 200 is coated with a resist layer 210 sensitive to the light from the radiation source 300 in the present embodiments. In some embodiments, the radiation source 300 generates extreme ultraviolet (EUV) light L1, and the resist layer 210 is a material sensitive to the EUV light. In some embodiments, the lithography apparatus 100 may include various optic components (e.g., mirrors) to direct the light L1 from the radiation source 300 onto a mask stage 120, particularly to a mask 400 secured on the mask stage 120.

The lithography apparatus 100 may also include the mask stage 120 configured to secure the mask 400. In some embodiments, the mask stage 120 includes an electrostatic chuck (e-chuck) used to secure the mask 400. In this context, the terms mask, photomask, and reticle are used interchangeably. In the present embodiments, the lithography apparatus 100 is an EUV lithography system, and the mask 400 is a reflective mask including a reflective multi-layer deposited on a substrate. In some other embodiments, the lithography apparatus 100 uses a transmissive lithography technique, the mask 400 is a transmissive mask including transparent substrate allowing the light from the radiation source 300 to transmit.

The lithography apparatus 100 may also include an optical module 140 for imaging the pattern of the mask 400 onto a semiconductor substrate 200 secured on a substrate stage (or wafer stage) 130 of the lithography apparatus 100. The optical module 140 may include reflective optics in the present embodiments. In some alternative embodiments, the optical module 140 may include refractive optics, reflective optics, or the combination thereof. Various components including those described above are integrated together over the exposure station ES and are operable to perform lithography exposing processes.

Over the measurement station MS, the lithography apparatus 100 may perform an inspection process over a semiconductor substrate 200 (e.g., one of the substrates 200a and 200b). The lithography apparatus 100 may include a light source 150, a fiber structure 160, a light receiver 170, and one or more optical components 182 and 184. The light source 150 may be vertically aligned with the substrate table 130b, while the light receiver 170 is not vertically aligned with the substrate table 130b. The fiber structure 160 has a fiber 162 and a fiber 164. The fiber 162 may extend along a direction substantially normal to a top surface of the semiconductor substrate 200. For example, an angle between an extension line of the fiber 162 and a direction normal to the top surface of the semiconductor substrate 200 may be in a range from about 80 degrees to about 100 degrees. In some alternative embodiments, for oblique inspection, other angles greater than about 100 degrees or less than about 80 degrees are applicable. The fiber 162 and the fiber 164 have first ends respectively optically coupled with the light source 150 and the light receiver 170, and second ends (e.g., collectively referred to as an end 1600 of the fiber structure 160) facing the semiconductor substrate 200 over the substrate table 130. With the configuration, the fiber 162 may direct light from the light source 150 to the semiconductor substrate 200, and the fiber 164 may receive light from the semiconductor substrate 200 to the light receiver 170. The optical component 182 may be coupled with the optical path of the fiber 162 from the light source 150 and the semiconductor substrate 200, and the and the optical component 184 may be coupled with the optical path of the fiber 164 from the semiconductor substrate 200 to the receiver 170.

The end 160O of the fiber structure 160 may be spaced apart from the semiconductor substrate 200 by a distance determined by depth of focus. If the end 160O of the fiber structure 160 is spaced apart from the semiconductor substrate 200 too far, the light intensity may be too weak to inspect the semiconductor substrate 200. If the end 160O of the fiber structure 160 is spaced apart from the semiconductor substrate 200 too near, the inspection result may be seriously influenced by background's signal noise ratio (SNR). In some embodiments, the end 160O of the fiber structure 160 may also be referred to as a fiber tip or a fiber probe.

The light source 150 may provide a light with a suitable spectrum for detecting elements, such as silver nanoparticles, copper ions, CO₂, the like, or the combination thereof. The spectrum of the light source 150 may cover the UV light (e.g., about 300 nm to about 400 nm) and/or visible light (e.g., about 380 nm to about 780 nm). The light spectrum of the light source 150 may be tuned to cover characteristic peak(s) of the element(s) to be detected. For example, for detecting copper ions, the light spectrum of the light source 150 would cover about 808 nanometers. For detecting silver nanoparticles, light spectrum of the light source 150 would cover about 532 nanometers. For detecting CO₂, light spectrum of the light source 150 would cover about 2500 nanometers. The light source 150 may be a broadband light source for detecting various elements using a single light source. For example, a coherent length of the light from the light source 150 may be less than about 20 micrometer, less than about 10 micrometers, or even less than about 5 micrometers. The light provided by the light source 150 may have a short wavelength, which is beneficial for high resolution. The light provided by the light source 150 may not substantially expose the resist layer 210 over the semiconductor substrate 200. As a result, a peak wavelength of the light source 150 may be different from a peak wavelength of the radiation source 300. For example, a peak wavelength of the radiation source 300 may be extreme ultraviolet (EUV) light, while a peak wavelength of the light source 150 may be in visible light spectrum or the deep ultraviolet light (DUV).

In some embodiments, the light receiver 170 may be a spectrometer or a power meter, capable of detecting an intensity of the light from the fiber structure 160. The coaxial fiber is used to guide the light path, and the light is irradiated from the middle core of the coaxial fiber to the test area (input). The test area may also be referred to as interested region. The reflected spectral information (output) on the test area may difference due to the flatness or dirtiness through other multi-cores parts. The substrate 200 may be moved for time-sequentially scanning plural test areas (i.e., interested region).

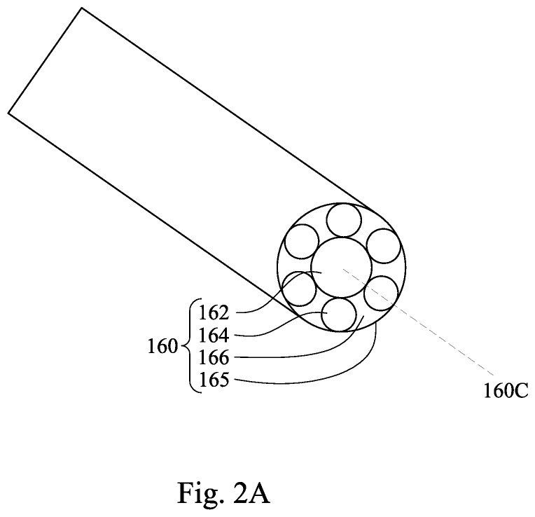

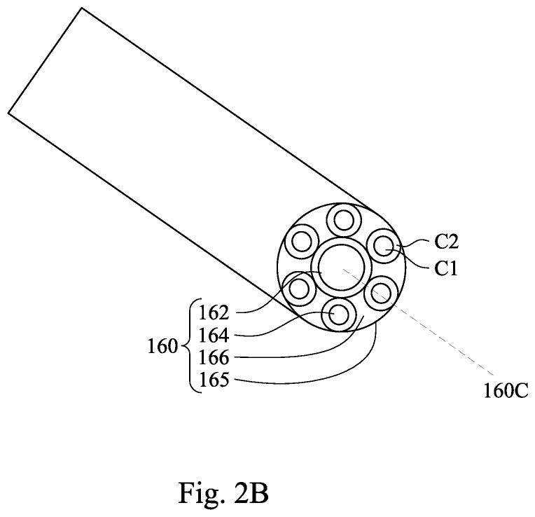

FIG. 2A is a schematic view of the fiber structure 160 in accordance with some embodiments. The fiber structure 160 may be a coaxial fiber. In the present embodiments, the first fiber 162 may be located at a center axis 160C of the coaxial fiber structure 160, and the second fibers 164 may be offset from the center axis 160C of the coaxial fiber structure 160, for example, arranged in a ring around the first fiber 162. In some embodiments, the first fiber 162 and the second fibers 164 may be arranged in other configurations. A diameter of the first fiber 162 may be different from a diameter of the second fibers 164. For example, in the present embodiments, a diameter of the first fiber 162 may be greater than a diameter of the second fibers 164. In some other embodiments, a diameter of the first fiber 162 may be equal to or less than a diameter of the second fibers 164.

The fiber structure 160 may have an outer jacket 165, serving as a wall surrounding the first fiber 162 and the second fibers 164. Material of the outer jacket 165 may include polyethylene, polyvinyl chloride, polyvinyl difluoride, the like, or the combination thereof. The fiber structure 160 may also have a filling material 166 filling the space among the first fiber 162, the second fibers 164, and the outer jacket 165. The filing material 166 may include suitable compounds. Reference is made to both FIGS. 2A and 2B. In some embodiments, the outer jacket 165 may only surround a portion 162B of the first fiber 162 and a portion 164B of the second fibers 164 adjacent to the substrates 200, which makes the portion 162B of the first fiber 162 and the portion 164B of the second fibers 164 to be a coaxial fiber. On the other hand, a portion 162A of the first fiber 162 and a portion 164A of the second fibers 164 may extend toward different targets (e.g., either light source or light receiver), and not be surround by the outer jacket 165.

In the present embodiments, the fiber structure 160 is a multi-core structure. For example, the fibers 162 and 164 is made of a light transmissive core material having a relatively high index of refraction and the filling material 166 is made of a cladding material having a relatively lower index of refraction than the light transmissive core material.

FIG. 2B is a schematic view of a fiber structure in accordance with some embodiments. Details of the present embodiments are similar to those illustrated in FIG. 2A, except that the fibers 162 and 164 are constructed of a light transmissive core material C1 having a relatively high index of refraction and surrounded by a cladding material C2 having a relatively lower index of refraction than that of the light transmissive core material C1. In the present embodiments, the filling material 166 may be made of any suitable material, not limit to be having a lower index of refraction than that of the light transmissive core material C1. In some alternative embodiments, the fibers 162 and 164 are a graded-index optical fiber in which the index of refraction in the core decreases continuously between the axis of the optical fiber and the boundary of the core with the cladding material. Other details of the present embodiments are similar to those mentioned above, and thereto not repeated herein.

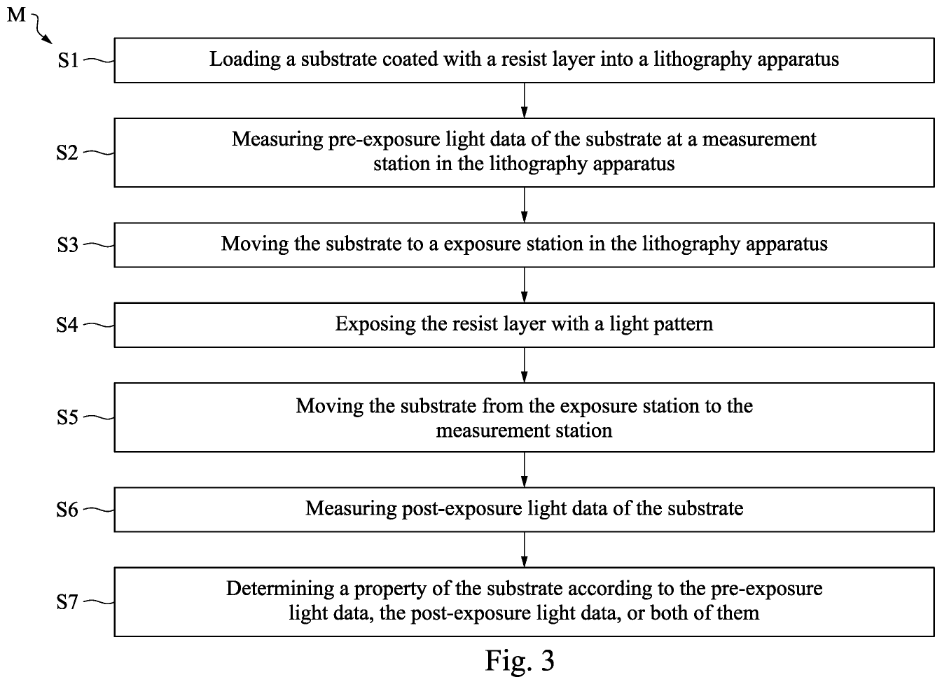

FIG. 3 is a flow chart of a method M for operating a lithography apparatus in accordance with some embodiments. The method M includes steps S1-S7. It is understood that additional steps may be provided before, during, and after the steps shown in FIG. 3, and some of the steps S1-S7 described can be replaced or eliminated for additional embodiments of the method. The order of the operations/processes may be interchangeable.

Reference is made to FIGS. 1 and 3. At step S1, a substrate 200 is coated with a resist layer 210 is loaded into a lithography apparatus 100. At step S2, pre-exposure light data of the substrate 200 are measured at the measurement station MS in the lithography apparatus 100. The measurement may be performed by using the light source 150, the fiber structure 160, the light receiver 170, and the optical components 182 and 184 at the measurement station MS. After measuring the pre-exposure light data of the substrate 200, the substrate 200 is moved to the exposure station ES in the lithography apparatus 100, as illustrated at step S3. In some embodiments, the steps S2 and S3 may be omitted.

At step S4, the resist layer 210 is exposed with a light pattern. After being exposed, the substrate 200 is moved from the exposure station ES to the measurement station MS as illustrated at step S5. Then, at step S6, post-exposure light data of the substrate is measured. The measurement may be performed by using the light source 150, the fiber structure 160, the light receiver 170, and the optical components 182 and 184 at the measurement station MS. Finally, at step S7, a property of the substrate (e.g., thickness of the coated resist layer 210, wafer surface height, particles, or the like) is determined according to the pre-exposure light data, the post-exposure light data, or both of them. By the method M, the exposure process can be monitored. In some embodiments, the step S7 may further include comparing the post-exposure light data with the pre-exposure light data, and the property of the substrate (e.g., thickness of the coated resist layer 210, wafer surface height, particles, or the like) is determined according to a comparing result (e.g., a difference between the post-exposure light data and the pre-exposure light data or a ratio of the post-exposure light data to the pre-exposure light data).

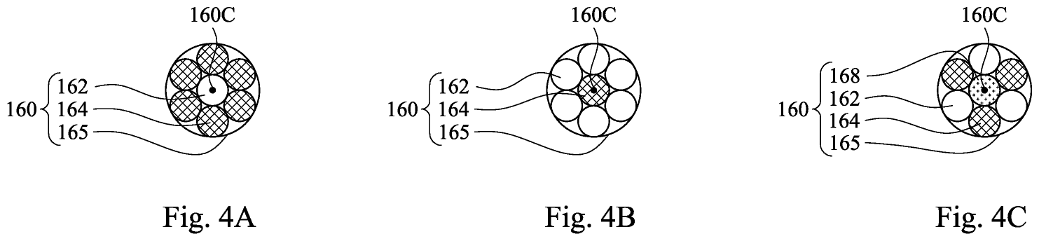

FIGS. 4A-4F are respectively cross-sectional views of fiber structures 160 in accordance with various embodiments. The cross-sections of the fiber structures 160 may affect light intensity and detection resolution. By adjusting the cross-sections of the fiber structures 160, the shape and intensity of light can be altered, and the spot of incidence and reflected light can also be adjusted.

Reference is made to FIG. 4A. In the present embodiments, the first fiber 162 may be located at center of the coaxial fiber, and the second fibers 164 may be disposed in a ring around the first fiber 162. In the present embodiments, a diameter of the first fiber 162 may be substantially equal to a diameter of the second fibers 164. In some other embodiments, a diameter of the first fiber 162 may be greater than or less than a diameter of the second fibers 164.

Reference is made to FIG. 4B. Embodiments of the present embodiments are similar to that of FIG. 4A, except that the configurations of the first fibers 162 and the second fibers 164 are exchanged in the present embodiments. In the present embodiments, the second fiber 164 may be located at a center axis 160C of the coaxial fiber structure 160, and the first fibers 162 may be offset from the center axis 160C of the coaxial fiber structure 160, for example, arranged in a ring around the second fiber 164. In the present embodiments, a diameter of the first fiber 162 may be substantially equal to a diameter of the second fibers 164. In some other embodiments, a diameter of the first fiber 162 may be greater than or less than a diameter of the second fibers 164. In some embodiments, the first fibers 162 may be coupled with a same light source 150. In some alternative embodiments, the first fibers 162 may be coupled with various light sources 150 with different spectrums. For example, a first group of the first fibers 162 are coupled with light with a first wavelength, a second group of the first fibers 162 are coupled with light with a second wavelength different from the first wavelength. Other details of the embodiments are similar to those illustrated above, and thereto not repeated herein.

Reference is made to FIG. 4C. In the present embodiments, a strength rod 168 may be located at center of the coaxial fiber, and the first and second fibers 162 and 164 may be disposed in a ring around the strength rod 164. The filling material 166 may fill the space among the first fiber 162, the second fibers 164, the strength rod 164, and the outer jacket 165. In the present embodiments, the first and second fibers 162 and 164 and the strength rod 168 may have a same diameter. In some other embodiments, two or three of the first and second fibers 162 and 164 and strength rod 168 may have different diameters.

Reference is made to FIG. 4D. Embodiments of the present embodiments is similar to that of FIG. 4A, except that the second fibers 164 include fibers 164A and 164B, in which a diameter of the fiber 164A is greater than a diameter of the fiber 164B. The fibers 164A and 164B may have diameters greater than, substantially equal to, or less than a diameter of the first fibers 162. For example, in the present embodiments, a diameter of the fibers 164A may be substantially equal to a diameter of the first fibers 162, and a diameter of the fibers 164B may be less than a diameter of the first fibers 162. The configurations of the first fibers 162 and the second fibers 164 may be exchanged in some alternative embodiments. Other details of the embodiments are similar to those illustrated above, and thereto not repeated herein.

Reference is made to FIG. 4E. Embodiments of the present embodiments is similar to that of FIG. 4A, except that the second fibers 164 include fibers 164A, 164B, 164C, in which a diameter of the fiber 164A is greater than a diameter of the fiber 164B, and the diameter of the fiber 164B is greater than a diameter of the fiber 164C. The fibers 164A, 164B, 164C may have diameters greater than, substantially equal to, or less than a diameter of the first fibers 162. For example, in the present embodiments, a diameter of the fibers 164A may be substantially equal to a diameter of the first fibers 162, a diameter of the fibers 164B may be less than a diameter of the fibers 162A, and a diameter of the fibers 164C may be less than a diameter of the first fibers 162. The configurations of the first fibers 162 and the second fibers 164 may be exchanged in some alternative embodiments. Other details of the embodiments are similar to those illustrated above, and thereto not repeated herein.

Reference is made to FIG. 4F. Embodiments of the present embodiments is similar to that of FIG. 4E, except that the fiber structure 160 is an elliptical fiber. For example, the fiber structure 160 may have a short axis and a long axis greater than the short axis. In some embodiments, the fiber structure 160 in FIGS. 4A-4E may also adopt the configuration of the elliptical fiber. Other details of the embodiments are similar to those illustrated above, and thereto not repeated herein.

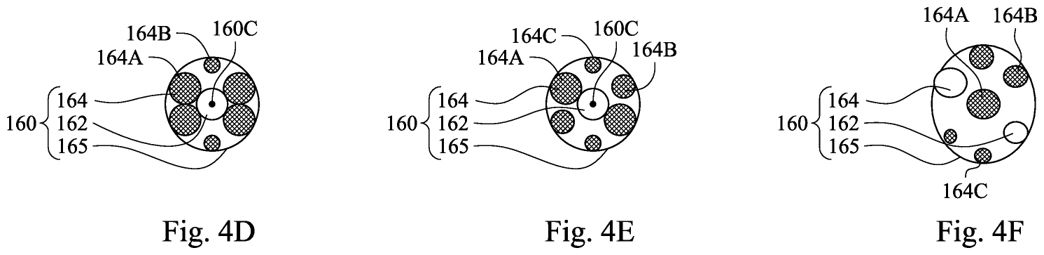

FIGS. 5A and 5B illustrate inspecting a substrate in accordance with various embodiments. Referring to FIG. 5A, in some cases without using the fiber structure 160, a light IL may be obliquely incident on the semiconductor substrate 200 for inspection. When the substrate 200 has recesses 200R, one or more particles 201 in the recesses 200R may not be inspected due to shadowing effect.

Referring to FIG. 5B, with the configuration of the fiber structure 160 (referring to FIG. 1), the light FL from the fiber structure 160 (referring to FIG. 1) may be vertically incident on the semiconductor substrate 200. In such configuration, particles 201 in the recesses 200R may be inspected.

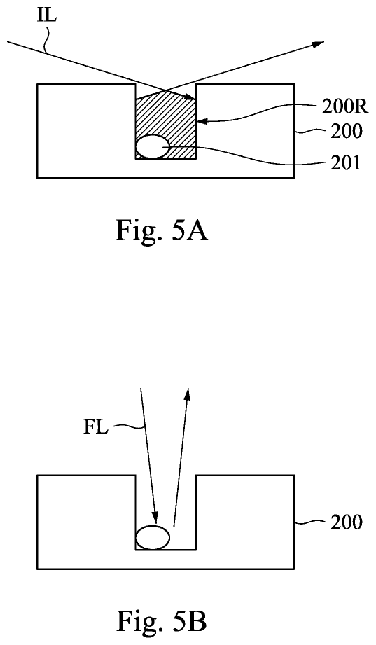

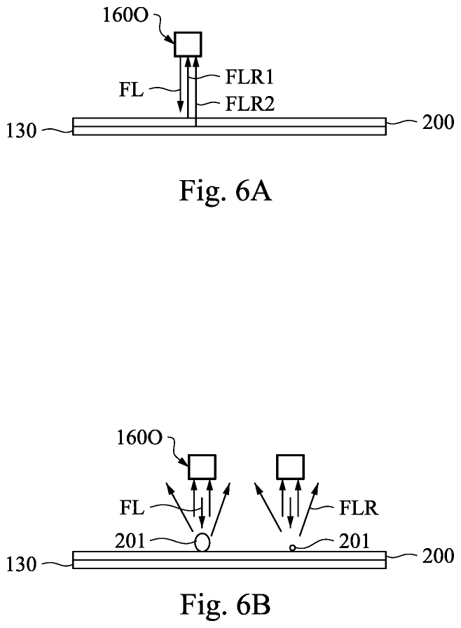

FIG. 6A is a schematic side view illustrating a method of inspecting a substrate in accordance with various embodiments. The light FL from the end 160O of the fiber structure 160 may be incident onto the substrate 200, and reflected by various interfaces as reflected light FLR1 and FLR2. The substrate 200 may be a semiconductor substrate or a mask (or reticle). The reflected light FLR1 and FLR2 may induce interference pattern, which can be directed to the light receiver 170 through the fiber structure 160, thereby being detected by the light receiver 170. A controller 190 (see FIG. 1) electrically coupled with the light receiver 170 may determine a thickness of the film over the substrate 200 based on the detected interference spectrum of the light receiver 170. The controller 190 (see FIG. 1) may include a computer-readable storage medium and a processor coupled to the computer-readable storage medium. The computer-readable storage medium stores program that controls various steps of the method M performed in the lithography apparatus 100. The controller 190 controls the operations of the exposure process, movement of the substrate table, and measurements of light data by using the processor reading out and executing the program stored in the storage medium. The program may be one that has been stored in the computer-readable storage medium, or may be one that has been installed to the storage medium of the controller 190.

FIG. 6B is a schematic side view illustrating a method of inspecting a substrate in accordance with various embodiments. The light FL from the end 160O of the fiber structure 160 may be incident onto the substrate 200, and reflected by the particles 201 over the substrate 200 as reflected light FLR. The reflected light FLR can be directed to the light receiver 170 through the fiber structure 160, thereby being detected by the light receiver 170. Through the configuration, the particles with different sizes can be detected. A controller 190 (see FIG. 1) electrically coupled with the light receiver 170 may determine the particles 201 over the substrate 200 or a tilt of the film over the substrate 200 based on the detected light spectrum of the light receiver 170.

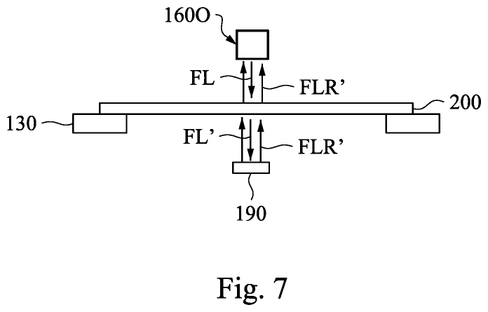

FIG. 7 is a schematic side view illustrating a method of inspecting a substrate in accordance with various embodiments. Details of the present embodiments are similar to those illustrated with FIGS. 6A and 6B, except that the light FL from the end 160O of the fiber structure 160 may be incident onto a sample 200′, and passes through the film 200′ as the light FL′. In some embodiments, the sample 200′ may be a pellicle protecting a mask. In some other embodiments, the sample 200′ may be a transmissive mask. A mirror 190 below the sample 200′ may reflect the light FL′, which is referred to the reflected light FLR. The reflected light FLR passes through the sample 200′ may be referred to as the reflected light FLR′. The reflected light FLR′ can be directed to the light receiver 170 through the fiber structure 160, thereby being detected by the light receiver 170. In some embodiments, a controller 190 (see FIG. 1) electrically coupled with the light receiver 170 may determine the particles 201 over the sample 200′ or a tilt of the film over the sample 200′ based on the detected light spectrum of the light receiver 170. In some embodiments, the reflected light FLR′ may include light reflected by multiple interfaces, thereby inducing interference, and the controller 190 (see FIG. 1) electrically coupled with the light receiver 170 may determine a thickness of the film over the sample 200′ based on the detected interference spectrum of the light receiver 170.

Based on the above discussions, it can be seen that the present disclosure offers advantages over semiconductor devices. It is understood, however, that other embodiments may offer additional advantages, and not all advantages are necessarily disclosed herein, and that no particular advantage is required for all embodiments. One advantage is that an input light from a co-axial fiber substantially vertically illuminates the surface of a workpiece, and the light is reflected as an output light and transmitted to a receiver through the same co-axial fiber, in which the inspection tool is applied to an exposure machine for measuring wafer flatness and cleanliness. Another advantage is that to simplify the optical path and facilitate surface detection, the fiber profile of the probe includes a multi-core structure. Still another advantage is that by using the fiber inspection tool, the inspection optical path is simplified, thereby resolving issues of abnormal detection, which may due to factors like earthquakes, optical component damage, and unusual optical path angles. Still another advantage is that by using the fiber inspection tool, the resolution is kept, the scanning speed is increased by adjusting the direction of the fiber probe, and the target area can be detected easily by adjusting the fiber probe.

According to some embodiments of the present disclosure, a lithography apparatus includes an exposure tool, a measurement tool, and a substrate table. The exposure tool is configured to provide a light pattern to a first position. The measurement tool includes a light source, a light receiver, and a fiber structure. The fiber structure has a first fiber, at least one second fiber, and a wall surrounding the first fiber and the second fiber. A first end of the first fiber is optically coupled with the light source, a first end of the second fiber is optically coupled with the light receiver, and a second end of the first fiber and a second end of the second fiber face a second position. The substrate table is configured to support a substrate. The substrate table is movable between the first position and the second position.

According to some embodiments of the present disclosure, an inspection method includes placing a substrate over a substrate table; measuring light data of the substrate when the substrate table is at a measurement station. Measuring the light data of the substrate comprises using a first fiber of a fiber structure, directing a beam from a light source onto a substrate; and using a second fiber of the fiber structure, directing a reflected beam from the substrate to a receiver, wherein the fiber structure comprises a wall surrounding a portion of the first fiber and a portion of the second fiber.

According to some embodiments of the present disclosure, a method for fabricating a semiconductor device is provided. The method includes coating a semiconductor substrate with a resist layer; loading the semiconductor substrate into a lithography apparatus; exposing the resist layer over the semiconductor substrate with a light pattern at an exposure station; and inspecting the semiconductor substrate at a measurement station, wherein inspecting the semiconductor substrate comprises directing a light beam to an area of the semiconductor substrate through a first fiber, and the first fiber extends in a direction substantially perpendicular to a top surface of the semiconductor substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A lithography apparatus, comprising:
an exposure tool configured to provide a light pattern to a first position; and
a measurement tool, comprising:
a light source;
a light receiver; and
a fiber structure having a first fiber, at least one second fiber, and a wall surrounding the first fiber and the second fiber, wherein a first end of the first fiber is optically coupled with the light source, a first end of the second fiber is optically coupled with the light receiver, and a second end of the first fiber and a second end of the second fiber face a second position; and
a substrate table configured to support a substrate, wherein the substrate table is movable between the first position and the second position.

2. The lithography apparatus of claim 1, wherein a diameter of the first fiber is different from a diameter of the second fiber.

3. The lithography apparatus of claim 1, wherein the first fiber is at a center axis of the fiber structure, and the second fiber is offset from the center axis of the fiber structure.

4. The lithography apparatus of claim 1, wherein a plurality of the second fibers surround the first fiber.

5. The lithography apparatus of claim 1, wherein the first fiber extends along a substantially straight line from the light source toward the substrate table.

6. The lithography apparatus of claim 1, wherein a portion of the first fiber near the second end of the first fiber and a portion of the second fiber near the second end of the second fiber are surrounded by the wall.

7. A method, comprising:
placing a substrate over a substrate table;
measuring light data of the substrate when the substrate table is at a measurement station, wherein measuring the light data of the substrate comprising:
using a first fiber of a fiber structure, directing a beam from a light source onto a substrate; and
using a second fiber of the fiber structure, directing a reflected beam from the substrate to a receiver, wherein the fiber structure comprises a wall surrounding a portion of the first fiber and a portion of the second fiber.

8. The method of claim 7, further comprising:
moving the substrate table to an exposure station; and
performing an exposure process on the substrate.

9. The method of claim 8, wherein measuring the light data of the substrate is performed after the exposure process.

10. The method of claim 8, wherein measuring the light data of the substrate is performed before the exposure process.

11. The method of claim 7, wherein the measured light data of the substrate is an interference spectrum.

12. The method of claim 7, wherein the measured light data of the substrate is a light intensity.

13. The method of claim 7, wherein the substrate is coated with a resist layer.

14. A method for performing lithography process, comprising:
coating a semiconductor substrate with a resist layer;
loading the semiconductor substrate into a lithography apparatus;
exposing the resist layer over the semiconductor substrate with a light pattern at an exposure station; and
inspecting the semiconductor substrate at a measurement station, wherein inspecting the semiconductor substrate comprises directing a light beam to a first area of the semiconductor substrate through a first fiber, and the first fiber extends in a direction substantially perpendicular to a top surface of the semiconductor substrate.

15. The method of claim 14, wherein exposing the resist layer is performed using extreme ultraviolet light.

16. The method of claim 14, further comprising:
moving the semiconductor substrate from the exposure station to the measurement station.

17. The method of claim 14, wherein exposing the resist layer over the semiconductor substrate with the light pattern at the exposure station is performed after inspecting the semiconductor substrate at the measurement station.

18. The method of claim 14, wherein exposing the resist layer over the semiconductor substrate with the light pattern at the exposure station is performed before inspecting the semiconductor substrate at the measurement station.

19. The method of claim 14, wherein inspecting the semiconductor substrate further comprises direct a light beam reflected by the area of the semiconductor substrate to a receiver through a second fiber.

20. The method of claim 14, wherein inspecting the semiconductor substrate further comprises direct the light beam to a second area of the semiconductor substrate through the first fiber.
